(19) United States
(12) Patent Application Publication
(10) Pub. No.: US 2024/0334786 A1
(43) Pub. Date: Oct. 3, 2024

(54) WINDOW MEMBER, DISPLAY DEVICE INCLUDING THE SAME, AND METHOD FOR MANUFACTURING DISPLAY DEVICE

(71) Applicant: Samsung Display Co., LTD., Yongin-si (KR)

(72) Inventor: JUNGKYU LEE, Yongin-si (KR)

(21) Appl. No.: 18/507,729

(22) Filed: Nov. 13, 2023

(30) Foreign Application Priority Data
Mar. 27, 2023 (KR) 10-2023-0039645

(51) Int. Cl. H10K 59/80; H10K 59/12

(52) U.S. Cl. CPC H10K 59/873; H10K 59/1201; H10K 2102/311

(57) ABSTRACT

A display device includes: a display panel including a non-folding region and a foldable region adjacent the non-folding region; and a window member on the display panel, and including a resin layer overlapping the non-folding region, and an adhesive layer including a first resin pattern overlapping the foldable region and a second resin pattern on the first resin pattern.

### CROSS-REFERENCE TO RELATED APPLICATION

The present application claims priority to and the benefit of Korean Patent Application No. 10-2023-0039645, filed on Mar. 27, 2023, in the Korean Intellectual Property Office, the entire content of which is hereby incorporated by reference.

### BACKGROUND

### 1. Field

Embodiments of the present disclosure relate to a window member, a display device including the window member, and a method for manufacturing the display device. For example, embodiments of the present disclosure relate to a window member having excellent or suitable folding characteristics and impact resistance, a display device including the window member, and a method for manufacturing the display device.

### 2. Description of Related Art

A display device refers to a device configured to display an image for providing visual information to a user. Among display devices, organic light emitting diode displays have recently been attracting attention.

A display device may include a display panel configured to output an image, and a window member configured to protect the display panel. The window member may have sufficient strength to protect the display panel from the external environment. In addition, the window member may have transparency suitable for transmitting the image output from the display panel.

Recently, flexible display devices have been developed. A flexible display device may be classified as a bendable display device, a foldable display device, a rollable display device, a stretchable display device, and/or the like depending on its purpose or its shape. The display panel and the window member of the flexible display device may include flexible materials so as to be flexibly deformable by an external force.

### SUMMARY

An aspect of one or more embodiments of the present disclosure relate to a window member having excellent or suitable folding characteristics and impact resistance.

An aspect of one or more embodiments of the present disclosure relate to a display device including the window member.

An aspect of one or more embodiments of the present disclosure relate to a method for manufacturing the display device.

Additional aspects will be set forth in part in the description which follows and, in part, will be apparent from the description, or may be learned by practice of the presented embodiments of the disclosure.

An window member according to one or more embodiments of the present disclosure includes a resin layer overlapping a non-folding region and an adhesive layer overlapping a foldable region, the foldable region being adjacent the non-folding region, and the adhesive layer including a first resin pattern, a second resin pattern on the first resin pattern, and a third resin pattern on the second resin pattern.

In one or more embodiments, the first resin pattern may include a plurality of first patterns repeatedly arranged with each other in a first direction and a second direction intersecting the first direction, the second resin pattern may include a plurality of second patterns repeatedly arranged with each other in the first direction and the second direction, and the third resin pattern may include a plurality of third patterns repeatedly arranged with each other in the first direction and the second direction.

In one or more embodiments, each of the first patterns, the second patterns, and the third patterns may have a hexagonal shape when viewed in a plan view.

A display device according to one or more embodiments of the present disclosure includes a display panel including a non-folding region and a foldable region adjacent the non-folding region and a window member on the display panel, and including a resin layer overlapping the non-folding region, and an adhesive layer including a first resin pattern overlapping the foldable region and a second resin pattern on the first resin pattern.

In one or more embodiments, the first resin pattern may include a plurality of first patterns repeatedly arranged with each other in a first direction and a second direction intersecting the first direction while being spaced and/or apart from (e.g., separated from) each other.

In one or more embodiments, the second resin pattern may include a plurality of second patterns repeatedly arranged with each other in the first direction and the second direction while being spaced and/or apart from (e.g., separated from) each other.

In one or more embodiments, the adhesive layer may further include a third resin pattern on the second resin pattern.

In one or more embodiments, the second resin pattern may be spaced and/or apart from (e.g., separated from) the first resin pattern in a third direction that is normal or perpendicular to a plane defined by the first direction and the second direction, and the third resin pattern may be spaced and/or apart from (e.g., separated from) the second resin pattern in the third direction.

In one or more embodiments, the third resin pattern may include a plurality of third patterns repeatedly arranged with each other in the first direction and the second direction while being spaced and/or apart from (e.g., separated from) each other.

In one or more embodiments, each of the first patterns, the second patterns, and the third patterns may have a polygonal shape when viewed in a plan view.

In one or more embodiments, each of the first patterns, the second patterns, and the third patterns may have a rectangular shape when viewed in the plan view.

In one or more embodiments, the resin layer, the first resin pattern, the second resin pattern, and the third resin pattern may include substantially the same material.

In one or more embodiments, each of the resin layer, the first resin pattern, the second resin pattern, and the third resin pattern may include at least one of (e.g., at least one selected from the group consisting of) a siloxane-based resin, an epoxy-based resin, an acryl-based resin, a polyvinyl alcohol-based resin, a polyacrylic acid, polyacrylimide, and a methylolated melamine resin.

In one or more embodiments, the display device may further include a protective layer on the window member, wherein the protective layer may include substantially the same material as the resin layer.

A method of manufacturing a display device according to one or more embodiments of the present disclosure includes forming a display panel including a non-folding region and a foldable region adjacent the non-folding region, forming a resin layer on the display panel and overlapping the non-folding region, forming a first adhesive layer on the display panel and overlapping the foldable region, forming a first resin pattern on the first adhesive layer, forming a second adhesive layer covering the first resin pattern; forming a second resin pattern on the second adhesive layer, and forming a third adhesive layer covering the second resin pattern.

In one or more embodiments, the method for manufacturing the display device may further include forming a third resin pattern on the third adhesive layer; and forming a fourth adhesive layer covering the third resin pattern.

In one or more embodiments, the first resin pattern may include a plurality of first patterns repeatedly arranged with each other in a first direction and a second direction intersecting the first direction, the second resin pattern may include a plurality of second patterns repeatedly arranged with each other in the first direction and the second direction, and the third resin pattern may include a plurality of third patterns repeatedly arranged with each other in the first direction and the second direction.

In one or more embodiments, each of the first patterns, the second patterns, and the third patterns may have a polygonal shape when viewed in a plan view.

In one or more embodiments, the first adhesive layer, the second adhesive layer, the third adhesive layer, and the fourth adhesive layer may include substantially the same material.

In one or more embodiments, the method for manufacturing the display device may further include forming a protective layer on the fourth adhesive layer and the resin layer, wherein the protective layer includes substantially the same material as the fourth adhesive layer.

According to one or more embodiments of the present disclosure, a display device may include a window member, and the window member may include an adhesive layer overlapping a foldable region, and may include a first resin pattern, a second resin pattern on the first resin pattern, and a third resin pattern on the second resin pattern. In addition, the window member may include a resin layer overlapping a non-folding region.

Accordingly, impact resistance of the display device may be improved. In addition, folding characteristics of the display device may be improved. In addition, a process of manufacturing the display device may be simplified.

However, aspects, embodiments, and/or effects of the present disclosure are not limited to the above-described effects, and may be variously expanded without departing from the spirit and scope of the present disclosure.

### BRIEF DESCRIPTION OF THE DRAWINGS

FIG. 1 is a plan view showing a display device according to one or more embodiments of the present disclosure.

FIG. 2 is a side view showing a folded state of the display device of FIG. 1, according to one or more embodiments of the present disclosure.

FIG. 3 is a sectional view showing a stacked structure of the display device of FIG. 1, according to one or more embodiments of the present disclosure.

FIG. 4 is an enlarged sectional view showing a window member of FIG. 3, according to one or more embodiments of the present disclosure.

FIGS. 5-7 are plan views showing the window member of FIG. 3, according to one or more embodiments of the present disclosure.

FIG. 8 is a plan view showing a window member according to one or more embodiments of the present disclosure.

FIG. 9 is a sectional view showing a pixel of FIG. 1, according to one or more embodiments of the present disclosure.

FIGS. 10-18 are sectional views showing a method for manufacturing a window member disposed on the display panel of FIG. 1, according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, embodiments of the present disclosure will be described in more detail with reference to the accompanying drawings. These embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Unless otherwise noted, like reference numerals denote like elements throughout the attached drawings and the written description, and thus, duplicative descriptions thereof may not be provided. In the drawings, the relative sizes of elements, layers, and regions may be exaggerated for clarity.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element or layer is referred to as being “on,” or “connected to” another element or layer, it can be directly on, or connected to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

As used herein, the singular forms “a,” “an” and “the” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

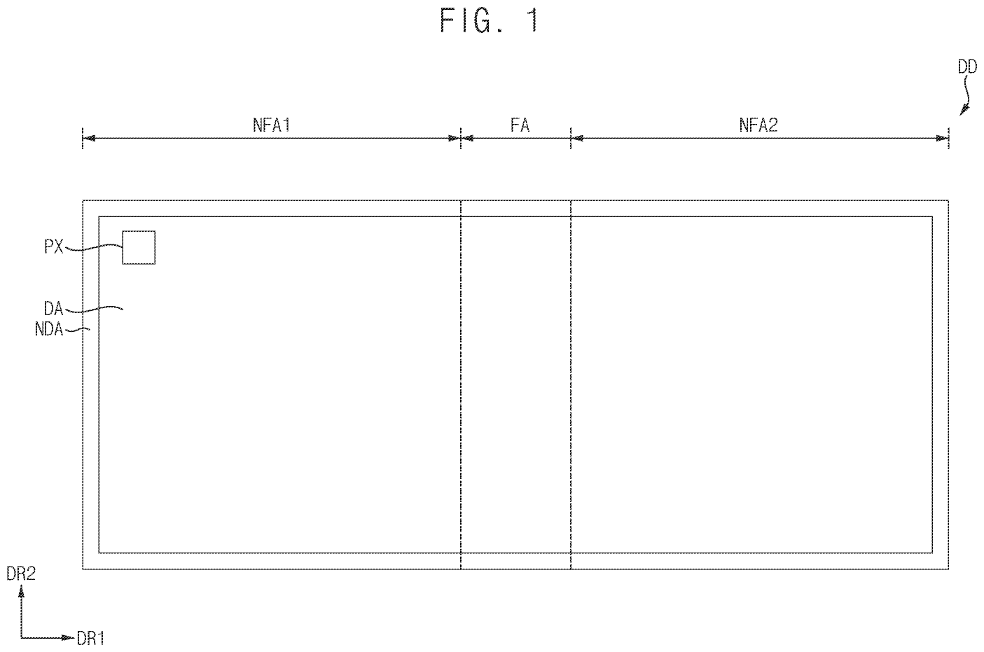

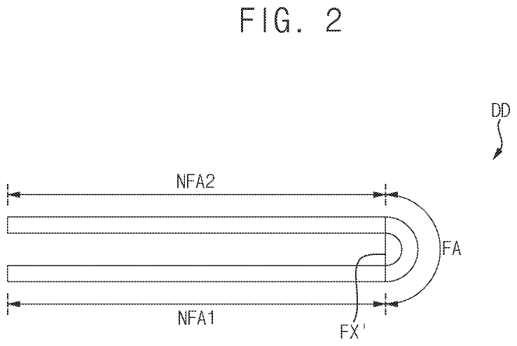

FIG. 1 is a plan view showing a display device according to one or more embodiments of the present disclosure. FIG. 2 is a view showing a folded state of the display device of FIG. 1 when viewed from a side view, according to one or more embodiments of the present disclosure. For example, FIG. 1 is a plan view showing a state in which the display device is not folded.

Referring to FIGS. 1 and 2, according to one or more embodiments of the present disclosure, a display device DD may include a display region DA and a non-display region NDA. The display region DA may be defined as a region capable of displaying an image by generating a light or adjusting a transmittance of a light provided from an external light source. The non-display region NDA may be a region in which an image is not displayed. In addition, the non-display region NDA may surround at least a portion of the display region DA.

A plurality of pixels PX may be disposed in the display region DA. Each of the pixels PX may be to emit a light. The pixels PX may be repeatedly arranged with each other in a first direction DR1 and a second direction DR2 intersecting the first direction DR1.

The display device DD may correspond to a foldable display device. For example, the display device DD may include a first non-folding region NFA1, a second non-folding region NFA2, and a foldable region FA. The foldable region FA may be disposed between the first non-folding region NFA1 and the second non-folding region NFA2. In one or more embodiments, the first non-folding region NFA1 and the second non-folding region NFA2 may be spaced and/or apart from (e.g., separated from) each other with the foldable region FA interposed therebetween.

The display device DD may be folded based on a folding axis FX′. The folding axis FX′ may extend in the second direction DR2. The foldable region FA may be folded so that the display device DD may be folded. In addition, the first non-folding region NFA1 and the second non-folding region NFA2 may not be folded.

According to embodiments of the present disclosure, the first direction DR1 and the second direction DR2 intersecting the first direction DR1 may be defined. In addition, a third direction DR3 that is perpendicular to a plane defined by the first direction DR1 and the second direction DR2 may be defined.

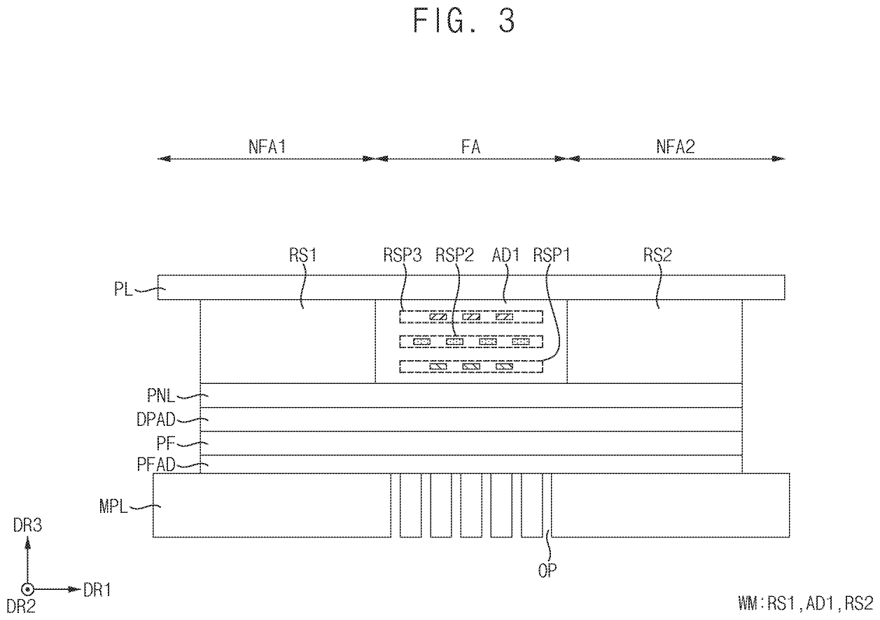

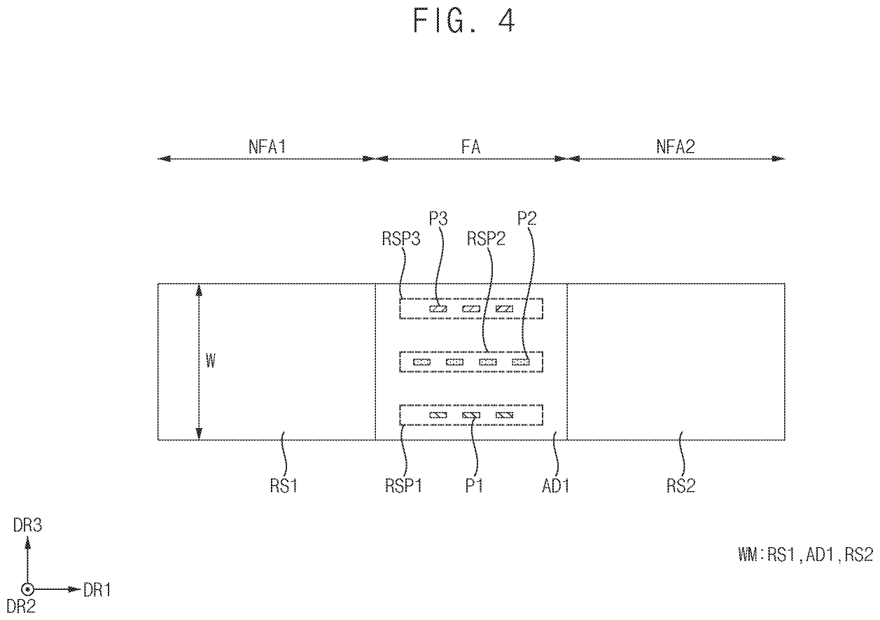

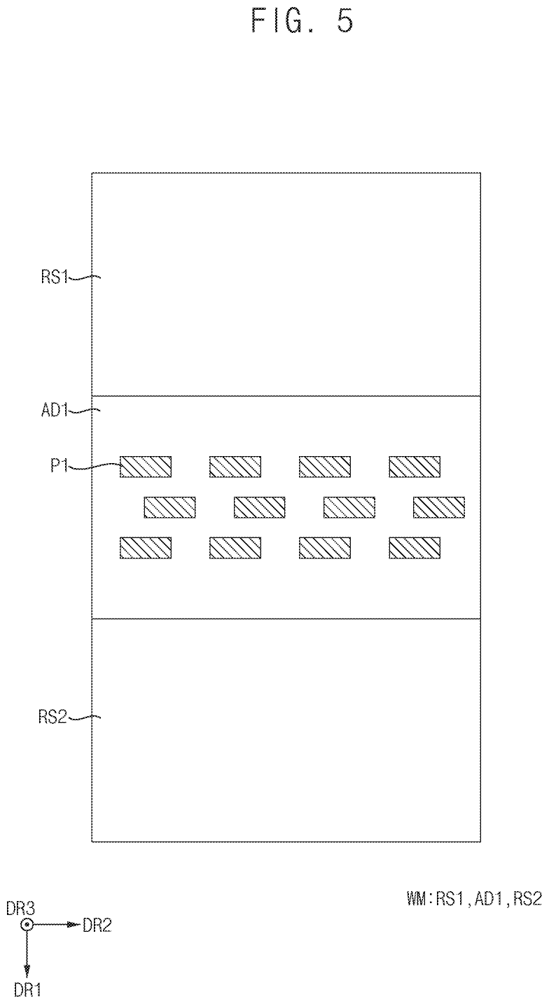

FIG. 3 is a sectional view showing a stacked structure of the display device of FIG. 1, according to one or more embodiments of the present disclosure. FIG. 4 is an enlarged sectional view showing a window member of FIG. 3, according to one or more embodiments of the present disclosure. FIGS. 5 to 7 are plan views showing the window member of FIG. 3, according to one or more embodiments of the present disclosure.

Referring to FIG. 3, the display device DD may include a plate MPL, a first adhesive layer AD1, a display panel adhesive layer DPAD, a protective film adhesive layer PFAD, a protective film PF, a display panel PNL, a window member WM, a protective layer PL, a first resin pattern RSP1, a second resin pattern RSP2, a third resin pattern RSP3, a first resin layer RS1, and a second resin layer RS2.

The plate MPL may be disposed under the protective film PF. The plate MPL may be attached to the protective film PF through the protective film adhesive layer PFAD. The plate MPL may support the display device DD. In one or more embodiments, the plate MPL may include a metal material. For example, the plate MPL may include stainless steel, aluminum, titanium, copper, and/or the like. These may be used alone or in combination with each other. However, the present disclosure is not limited thereto, and the plate MPL may include other suitable types (kinds) of materials.

A plurality of openings OP may be defined in a portion of the plate MPL overlapping the foldable region FA. Since the openings OP are defined in the plate MPL, the portion of the plate MPL overlapping the foldable region FA may be folded. The protective film adhesive layer PFAD may be disposed on the plate MPL.

The protective film adhesive layer PFAD may provide adhesive strength to the protective film PF. For example, the protective film adhesive layer PFAD may include an optical clear adhesive (OCA), an optical clear resin (OCR), a pressure sensitive adhesive (PSA), and/or the like. These may be used alone or in combination with each other.

The protective film PF may be disposed on the protective film adhesive layer PFAD. The protective film PF may protect a bottom surface of the display panel PNL. For example, the protective film PF may include polyethylene terephthalate (PET), polyimide (PI), polyethylene naphthalate (PEN), and/or the like. These may be used alone or in combination with each other.

The display panel adhesive layer DPAD may be disposed on the protective film PF. The display panel adhesive layer DPAD may be disposed under the display panel PNL to provide adhesive strength to the display panel PNL. The display panel adhesive layer DPAD may include an OCA, an OCR, a PSA, and/or the like. These may be used alone or in combination with each other.

The display panel PNL may be disposed on the display panel adhesive layer DPAD. The display panel PNL may include a plurality of pixels PX. Each of the pixels PX may be to emit a light. In addition, the window member WM may be disposed on the display panel PNL.

The protective layer PL may be disposed on the window member WM. The protective layer PL may protect the window member WM from an external impact. In one or more embodiments, the protective layer PL may include phenylene, polyethylene terephthalate, polyimide, polyamide (PA), polyethylene naphthalate, polycarbonate (PC), and/or the like. These may be used alone or in combination with each other.

According to one or more embodiments, the protective layer PL may include a synthetic resin material. For example, the protective layer PL may include a siloxane-based resin, an epoxy-based resin, an acryl-based resin, a polyester-based resin, a polyether-based resin, an acrylate-based resin, and/or the like. These may be used alone or in combination with each other.

Referring to FIGS. 4 to 7, the window member WM may include the first resin layer RS1, the second resin layer RS2, and the first adhesive layer AD1. The first resin layer RS1 may overlap the first non-folding region NFA1. For example, the first resin layer RS1 may include a siloxane-based resin, an epoxy-based resin, an acryl-based resin, a polyvinyl alcohol-based resin, a polyacrylic acid, polyacrylimide, methylolated melamine, a butyric acid, and/or the like. These may be used alone or in combination with each other. However, the present disclosure is not limited thereto, and the first resin layer RS1 may include one or more other suitable materials.

The second resin layer RS2 may overlap the second non-folding region NFA2. For example, the second resin layer RS2 may include a siloxane-based resin, an epoxy-based resin, an acryl-based resin, a polyvinyl alcohol-based resin, a polyacrylic acid, polyacrylimide, methylolated melamine, a butyric acid, and/or the like. These may be used alone or in combination with each other. However, the present disclosure is not limited thereto, and the second resin layer RS2 may include one or more other suitable materials.

The first adhesive layer AD1 may overlap the foldable region FA. In one or more embodiments, the first adhesive layer AD1 may be disposed between the first resin layer RS1 and the second resin layer RS2. For example, the first adhesive layer AD1 may include an OCR.

The first adhesive layer AD1 may include a plurality of first patterns P1. In one or more embodiments, the first patterns P1 may be disposed inside the first adhesive layer AD1. The first patterns P1 may be repeatedly arranged with each other in the first direction DR1 and the second direction DR2.

In one or more embodiments, the first patterns P1 may be spaced and/or apart from (e.g., separated from) each other. FIG. 5 shows an example in which 12 first patterns P1 are provided. However, this is merely an example number, and the number of the first patterns P1 may be variously changed. In one or more embodiments, an interval between the first patterns P1 may also be suitably changed.

For example, the first patterns P1 may include a siloxane-based resin, an epoxy-based resin, an acryl-based resin, a polyvinyl alcohol-based resin, a polyacrylic acid, polyacrylimide, methylolated melamine, a butyric acid, and/or the like. These may be used alone or in combination with each other. However, the present disclosure is not limited thereto, and the first patterns P1 may include one or more other suitable materials.

In addition, the first patterns P1 may be collectively referred to as a first resin pattern RSP1.

The first adhesive layer AD1 may include a plurality of second patterns P2. For example, the second patterns P2 may be disposed inside the first adhesive layer AD1. In one or more embodiments, the second patterns P2 may be disposed on the first patterns P1. The second patterns P2 may be repeatedly arranged with each other in the first direction DR1 and the second direction DR2.

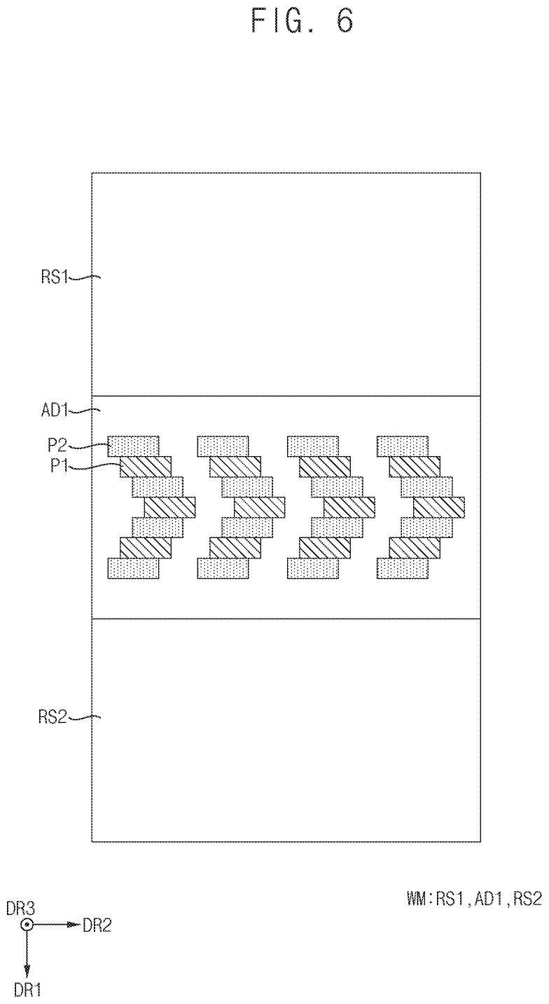

In one or more embodiments, the second patterns P2 may be spaced and/or apart from (e.g., separated from) each other. FIG. 6 shows an example in which 16 second patterns P2 are provided. However, this is only an example number, and the number of the second patterns P2 may be suitably changed. In one or more embodiments, an interval between the second patterns P2 may also be suitably changed.

In one or more embodiments, the second patterns P2 may not overlap the first patterns P1.

According to one or more embodiments, the second patterns P2 may entirely overlap the first patterns P1. According to one or more embodiments, the second patterns P2 may partially overlap the first patterns P1. If (e.g., when) the second patterns P2 and the first patterns P1 partially overlap each other or do not overlap each other, impact resistance of the window member WM may be further improved. Therefore, the second patterns P2 and the first patterns P1 may partially overlap each other, or may not overlap each other.

For example, the second patterns P2 may include a siloxane-based resin, an epoxy-based resin, an acryl-based resin, a polyvinyl alcohol-based resin, a polyacrylic acid, polyacrylimide, methylolated melamine, a butyric acid, and/or the like. These may be used alone or in combination with each other. However, the present disclosure is not limited thereto, and the second patterns P2 may include one or more other suitable materials.

In addition, the second patterns P2 may be collectively referred to as a second resin pattern RSP2. The second resin pattern RSP2 may be spaced and/or apart from (e.g., separated from) the first resin pattern RSP1 in the third direction DR3.

The first adhesive layer AD1 may include a plurality of third patterns P3. In one or more embodiments, the third patterns P3 may be disposed inside the first adhesive layer AD1. In one or more embodiments, the third patterns P3 may be disposed on the second patterns P2. The third patterns P3 may be repeatedly arranged with each other in the first direction DR1 and the second direction DR2.

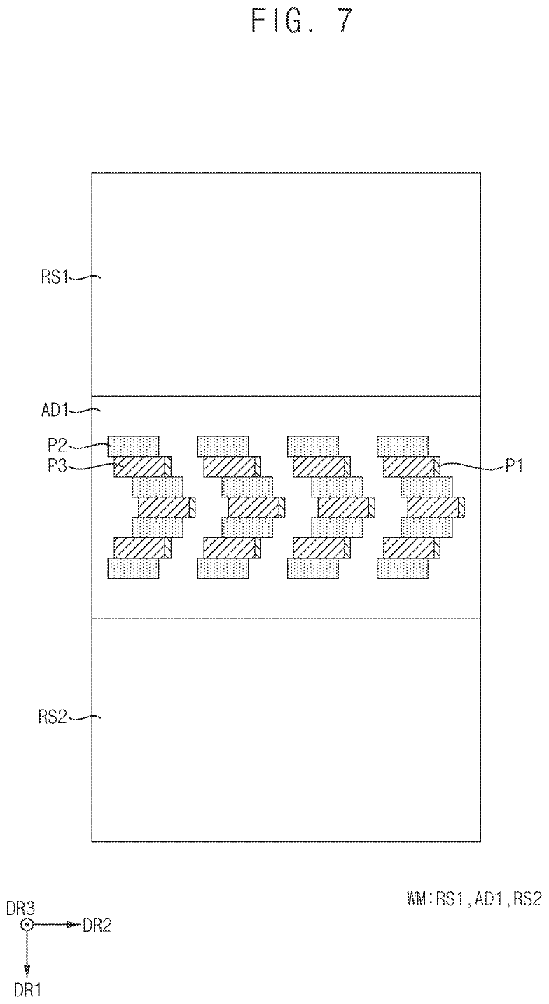

In one or more embodiments, the third patterns P3 may be spaced and/or apart from (e.g., separated from) each other. FIG. 7 shows an example in which 12 third patterns P3 are provided. However, this is merely an example number, and the number of the third patterns P3 may be suitably changed. In one or more embodiments, an interval between the third patterns P3 may also be suitably changed.

In one or more embodiments, the third patterns P3 may partially overlap the first patterns P1. According to one or more embodiments, the third patterns P3 may entirely overlap the first patterns P1. According to one or more embodiments, the third patterns P3 may not overlap the first patterns P1.

In one or more embodiments, the third patterns P3 may not overlap the second patterns P2. According to one or more embodiments, the third patterns P3 may entirely overlap the second patterns P2. According to one or more embodiments, the third patterns P3 may partially overlap the second patterns P2.

For example, the third patterns P3 may include a siloxane-based resin, an epoxy-based resin, an acryl-based resin, a polyvinyl alcohol-based resin, a polyacrylic acid, polyacrylimide, methylolated melamine, a butyric acid, and/or the like. These may be used alone or in combination with each other. However, the present disclosure is not limited thereto, and the third patterns P3 may include one or more other suitable materials.

In addition, the third patterns P3 may be collectively referred to as a third resin pattern RSP3. The third resin pattern RSP3 may be spaced and/or apart from (e.g., separated from) the second resin pattern RSP2 in the third direction DR3.

FIGS. 4 and 7 may show one example in which the first adhesive layer AD1 includes first to third resin patterns RSP1, RSP2, and RSP3. However, the present disclosure is not limited thereto, and the first adhesive layer AD1 may include at least four resin patterns. For example, the first adhesive layer AD1 may include a fourth resin pattern disposed on the third resin pattern RSP3 and a fifth resin pattern disposed on the fourth resin pattern.

In one or more embodiments, the first resin layer RS1 and the second resin layer RS2 may include substantially the same material. According to one or more embodiments, the first resin layer RS1 and the second resin layer RS2 may include different materials (e.g., substantially different materials).

In one or more embodiments, the first patterns P1, the second patterns P2, and the third patterns P3 may include substantially the same material. According to one or more embodiments, only some of the first patterns P1, the second patterns P2, and the third patterns P3 may include substantially the same material. For example, the first patterns P1 may include substantially the same material as the second patterns P2, and may include a material that is different from a material of the third patterns P3. According to one or more embodiments, the first patterns P1, the second patterns P2, and the third patterns P3 may include different materials (e.g., substantially different materials).

In one or more embodiments, the first resin layer RS1, the first patterns P1, the second patterns P2, and the third patterns P3 may include substantially the same material. In one or more embodiments, the first resin layer RS1, the first patterns P1, the second patterns P2, the third patterns P3, and the second resin layer RS2 may include substantially the same material.

In one or more embodiments, the first resin layer RS1, the second resin layer RS2, and the protective layer (e.g., the protective layer PL as shown in FIG. 3) may include substantially the same material. According to one or more embodiments, the protective layer PL may include a material that is different from a material of the first and second resin layers RS1 and RS2.

In one or more embodiments, each of the first patterns P1, the second patterns P2, and the third patterns P3 may have a polygonal shape when viewed in a plan view. For example, each of the first patterns P1, the second patterns P2, and the third patterns P3 may have a rectangular shape when viewed in a plan view.

In one or more embodiments, a width W of each of the first resin layer RS1, the second resin layer RS2, and the first adhesive layer AD1 (as shown, e.g., in FIG. 4) may be greater than or equal to 100 micrometers (μm). If (e.g., when) the width W of each of the first resin layer RS1, the second resin layer RS2, and the first adhesive layer AD1 is less than 100 micrometers, strength and impact resistance of the window member WM may deteriorate.

As described above, each of the first resin layer RS1 and the second resin layer RS2 may include a siloxane-based resin, an epoxy-based resin, an acryl-based resin, and/or the like. The siloxane-based resin, the epoxy-based resin, the acryl-based resin, and/or the like may correspond to a curing resin having high strength. Therefore, strength and impact resistance of a portion of the window member WM overlapping the first non-folding region NFA1 and the second non-folding region NFA2 may be improved.

The first adhesive layer AD1 overlapping the foldable region FA may include an OCR. The OCR may be provided in a liquid state. Therefore, folding characteristics of the first adhesive layer AD1 may be improved. In addition, the first adhesive layer AD1 may include the first resin pattern RSP1, the second resin pattern RSP2, and the third resin pattern RSP3. Accordingly, strength and impact resistance of the first adhesive layer AD1 may also be improved. For example, the window member WM may have excellent or suitable impact resistance and strength as well as excellent or suitable folding characteristics.

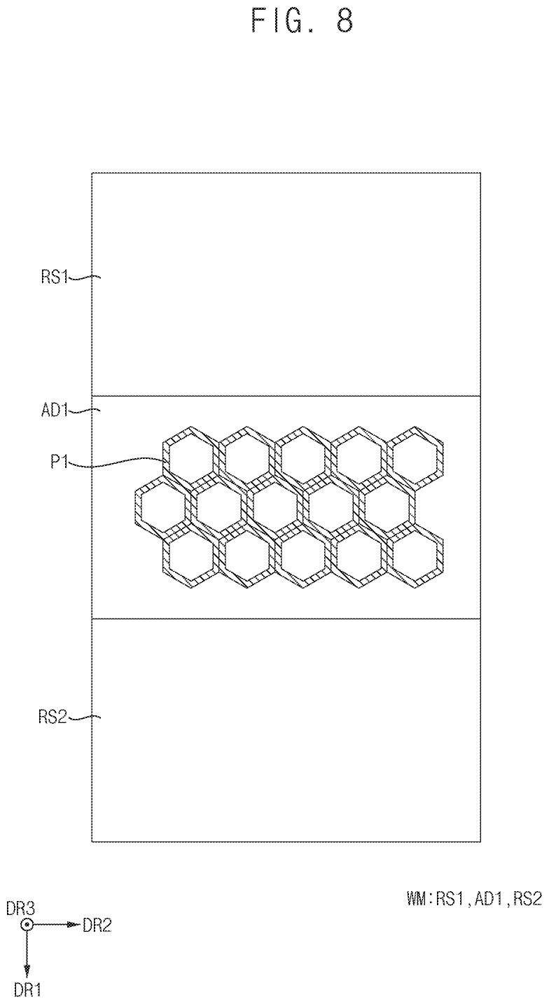

FIG. 8 is a plan view showing a window member according to one or more embodiments of the present disclosure.

Referring to FIGS. 3 and 8, each of the first patterns P1 may have a hexagonal shape when viewed in a plan view. For example, each of the first patterns P1 may have a hollow hexagonal shape. In addition, the first patterns P1 may make contact with each other. Accordingly, the impact resistance of the first adhesive layer AD1 may be improved. For example, the impact resistance of the first adhesive layer AD1 may be higher in a case where each of the first patterns P1 has a hexagonal shape when viewed in a plan view as shown in FIG. 8 as compared with a case where each of the first patterns P1 has a rectangular shape when viewed in a plan view as shown in FIG. 5.

Similar to the first patterns P1, each of the second patterns P2 and the third patterns P3 may also have a hexagonal shape when viewed in a plan view. However, the present disclosure is not limited thereto, and each of the first patterns P1, the second patterns P2, and the third patterns P3 may have a shape that is different from a rectangular shape or a hexagonal shape when viewed in a plan view. For example, each of the first patterns P1, the second patterns P2, and the third patterns P3 may have a circular shape when viewed in a plan view.

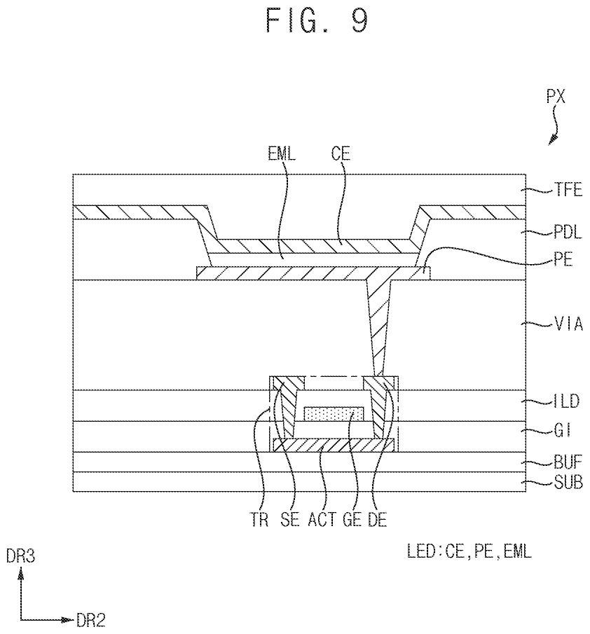

FIG. 9 is a sectional view showing a pixel of FIG. 1, according to one or more embodiments of the present disclosure.

Referring to FIG. 9, each of the pixels PX may include a substrate SUB, a buffer layer BUF, a gate insulating layer GI, an interlayer insulating layer ILD, a via insulating layer VIA, an active layer ACT, a source electrode SE, a gate electrode GE, a drain electrode DE, a pixel electrode PE, a pixel defining layer PDL, a light emitting layer EML, a common electrode CE, and an encapsulation layer TFE.

The substrate SUB may include a transparent material or an opaque material. The substrate SUB may be (e.g., may be configured as) a transparent resin substrate. Examples of the transparent resin substrate include a polyimide substrate and/or the like. In one or more embodiments, the polyimide substrate may include a first organic layer, a first barrier layer, a second organic layer, and/or the like. In one or more embodiments, the substrate SUB may include a quartz substrate, a synthetic quartz substrate, a calcium fluoride substrate, a fluorine-doped (F-doped) quartz substrate, a soda lime glass substrate, a non-alkali glass substrate, and/or the like. These may be used alone or in combination with each other.

The buffer layer BUF may be disposed on the substrate SUB. The buffer layer BUF may prevent or substantially prevent metal atoms or impurities from diffusing from the substrate SUB into a transistor. The transistor may include the source electrode SE, the drain electrode DE, the gate electrode GE, and the active layer ACT.

In one or more embodiments, if (e.g., when) a surface of the substrate SUB is not substantially uniform, the buffer layer BUF may improve flatness of the surface of the substrate SUB. For example, the buffer layer BUF may include an inorganic material such as silicon oxide, silicon nitride, and/or silicon oxynitride. These may be used alone or in combination with each other.

The active layer ACT may be disposed on the buffer layer BUF. The active layer ACT may include a metal oxide semiconductor, an inorganic semiconductor (e.g., amorphous silicon or polysilicon), an organic semiconductor, and/or the like. The active layer ACT may include a source region, a drain region, and a channel region located between the source region and the drain region.

The metal oxide semiconductor may include a binary compound (ABₓ), a ternary compound (ABₓC_{y}), a quaternary compound (ABₓC_{y}D_{z}), and/or the like including indium (In), zinc (Zn), gallium (Ga), tin (Sn), titanium (Ti), aluminum (Al), hafnium (Hf), zirconium (Zr), magnesium (Mg), and/or the like. For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), and/or the like. These may be used alone or in combination with each other.

The gate insulating layer GI may be disposed on the buffer layer BUF. The gate insulating layer GI may sufficiently cover the active layer ACT, and may have a substantially flat top surface without creating a step around the active layer ACT. In one or more embodiments, the gate insulating layer GI may be disposed along a profile of the active layer ACT to cover the active layer ACT. For example, the gate insulating layer GI may include an inorganic material such as silicon oxide (SiOₓ), silicon nitride (SiNₓ), silicon carbide (SiCₓ), silicon oxynitride (SiOₓN_{y}), and silicon oxycarbide (SiOₓC_{y}). These may be used alone or in combination with each other.

The gate electrode GE may be disposed on the gate insulating layer GI. The gate electrode GE may overlap the channel region of the active layer ACT.

The gate electrode GE may include a metal, an alloy, metal nitride, conductive metal oxide, a transparent conductive material, and/or the like. Examples of the metal include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and/or the like. Examples of the conductive metal oxide include indium tin oxide, indium zinc oxide, and/or the like. In addition, examples of the metal nitride include aluminum nitride (AlNₓ), tungsten nitride (WNₓ), chromium nitride (CrNₓ), and/or the like. These may be used alone or in combination with each other.

The interlayer insulating layer ILD may be disposed on the gate insulating layer GI. The interlayer insulating layer ILD may sufficiently cover the gate electrode GE, and may have a substantially flat top surface without creating a step around the gate electrode GE. In one or more embodiments, the interlayer insulating layer ILD may be disposed along a profile of the gate electrode GE to cover the gate electrode GE. For example, the interlayer insulating layer ILD may include an inorganic material such as silicon oxide, silicon nitride, silicon carbide, silicon oxynitride, and silicon oxycarbide. These may be used alone or in combination with each other.

The source electrode SE may be disposed on the interlayer insulating layer ILD. The source electrode SE may be connected to the source region of the active layer ACT through a contact hole formed through the gate insulating layer GI and the interlayer insulating layer ILD.

The drain electrode DE may be disposed on the interlayer insulating layer ILD. The drain electrode DE may be connected to the drain region of the active layer ACT through a contact hole formed through the gate insulating layer GI and the interlayer insulating layer ILD.

For example, the source electrode SE may include a metal, an alloy, metal nitride, conductive metal oxide, a transparent conductive material, and/or the like. These may be used alone or in combination with each other. The drain electrode DE may be formed through substantially the same process as the source electrode SE, and may include substantially the same material as the source electrode SE.

The via insulating layer VIA may be disposed on the interlayer insulating layer ILD. The via insulating layer VIA may cover (e.g., sufficiently cover) the source electrode SE and the drain electrode DE. The via insulating layer VIA may include an organic material. For example, the via insulating layer VIA may include an organic material such as a phenol resin, an acryl resin (polyacrylate resin), a polyimide resin, a polyamide resin, a siloxane resin, and an epoxy resin These may be used alone or in combination with each other.

The pixel electrode PE may be disposed on the via insulating layer VIA. The pixel electrode PE may be connected to the drain electrode DE through a contact hole formed through the via insulating layer VIA.

The pixel electrode PE may include a metal, an alloy, metal nitride, conductive metal oxide, a transparent conductive material, and/or the like. These may be used alone or in combination with each other. In one or more embodiments, the pixel electrode PE may have a stacked structure including ITO/Ag/ITO. For example, the pixel electrode PE may operate as (e.g., may be) an anode.

The pixel defining layer PDL may be disposed on the via insulating layer VIA. The pixel defining layer PDL may cover both side portions of the pixel electrode PE. In one or more embodiments, an opening exposing a portion of a top surface of the pixel electrode PE may be defined in the pixel defining layer PDL. For example, the pixel defining layer PDL may include an inorganic material or an organic material. In one or more embodiments, the pixel defining layer PDL may include an organic material such as an epoxy resin and a siloxane resin. These may be used alone or in combination with each other. According to one or more embodiments, the pixel defining layer PDL may further include a light blocking material including a black pigment, a black dye, and/or the like.

The light emitting layer EML may be disposed on the pixel electrode PE. The light emitting layer EML may include an organic material for emitting a light having a set or predetermined color. For example, the light emitting layer EML may include an organic material for emitting a light having a red color. However, the present disclosure is not limited thereto.

The common electrode CE may be disposed on the light emitting layer EML and the pixel defining layer PDL. The common electrode CE may include a metal, an alloy, metal nitride, conductive metal oxide, a transparent conductive material, and/or the like. These may be used alone or in combination with each other. The common electrode CE may operate as (e.g., may be) a cathode.

A light emitting element LED may include a pixel electrode PE, a light emitting layer EML, and a common electrode CE.

The encapsulation layer TFE may be disposed on the common electrode CE. The encapsulation layer TFE may prevent or substantially prevent impurities, moisture, and/or the like from penetrating into the light emitting element LED from an outside. The encapsulation layer TFE may include at least one inorganic layer and at least one organic layer. For example, the inorganic layer may include silicon oxide, silicon nitride, silicon oxynitride, and/or the like. These may be used alone or in combination with each other. The organic layer may include a cured material of a polymer such as polyacrylate.

Although the pixels PX have been described with reference to FIG. 9, the present disclosure is not limited to the structure shown in FIG. 9. In one or more embodiments of the present disclosure, each of the pixels PX may include any suitable structure configured to receive an electrical signal to emit a light having a luminance corresponding to an intensity of the electrical signal.

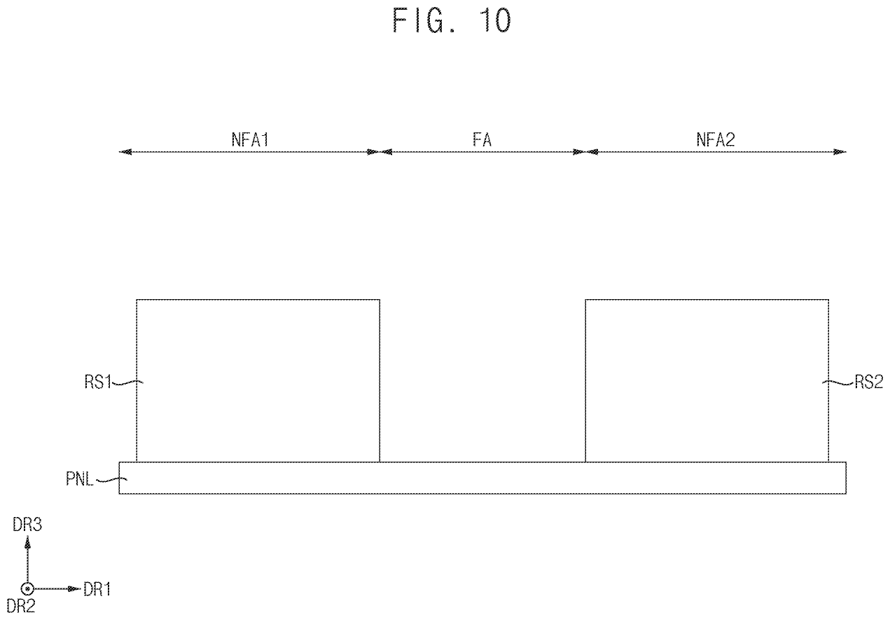

FIGS. 10 to 18 are sectional views showing a method for manufacturing a window member disposed on the display panel of FIG. 1, according to one or more embodiments of the present disclosure.

Referring to FIG. 10, a first resin layer RS1 and a second resin layer RS2 may be formed on a display panel PNL. The first resin layer RS1 may overlap a first non-folding region NFA1. In one or more embodiments, the second resin layer RS2 may overlap a second non-folding region NFA2.

For example, each of the first resin layer RS1 and the second resin layer RS2 may be formed to include a siloxane-based resin, an epoxy-based resin, an acryl-based resin, a polyvinyl alcohol-based resin, a polyacrylic acid, polyacrylimide, methylolated melamine, a butyric acid, and/or the like. These may be used alone or in combination with each other. However, the present disclosure is not limited thereto, and each of the first resin layer RS1 and the second resin layer RS2 may be formed to include one or more other suitable materials.

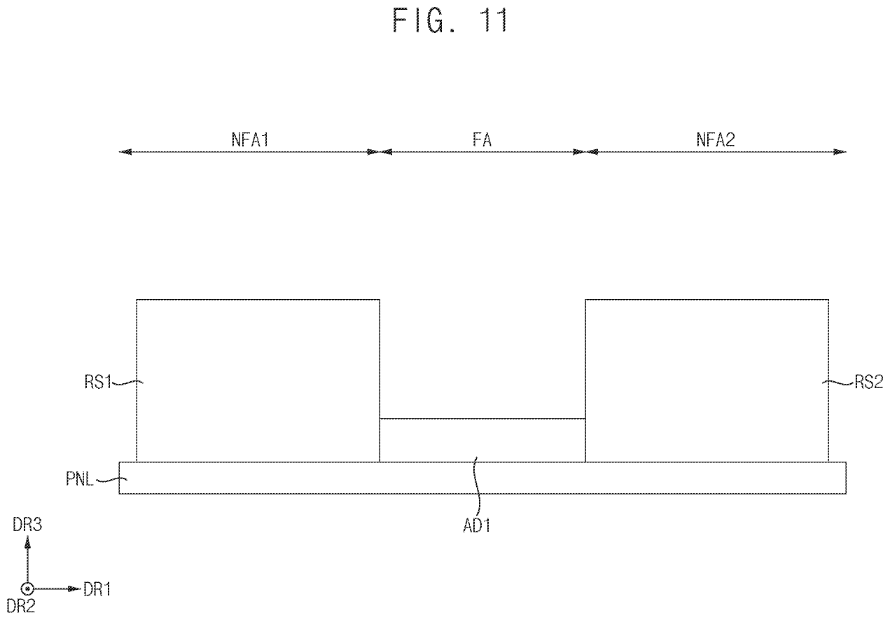

Referring to FIG. 11, a first adhesive layer AD1 may be formed on the display panel PNL. The first adhesive layer AD1 may overlap a foldable region FA. For example, the first adhesive layer AD1 may include an OCR.

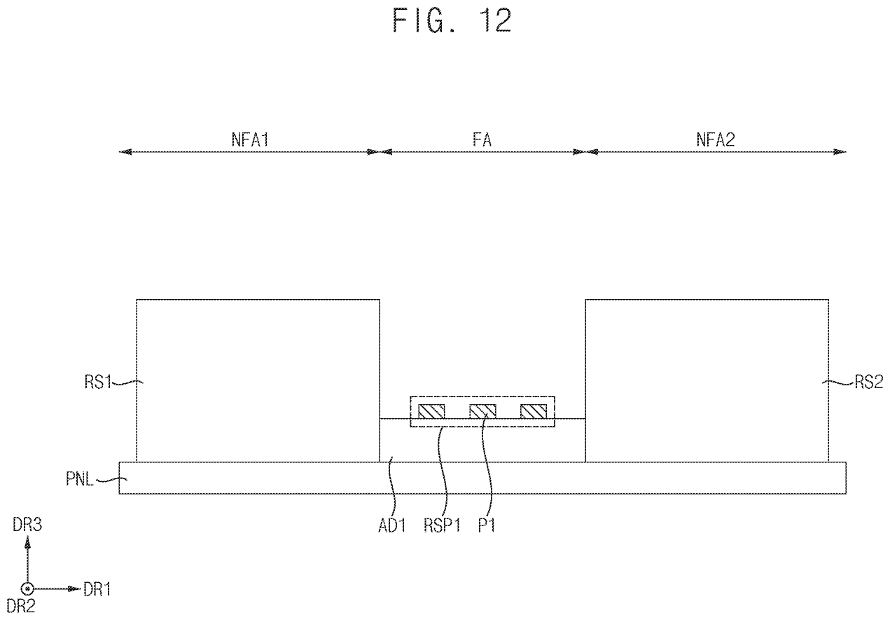

Referring to FIG. 12, a first resin pattern RSP1 may be formed on the first adhesive layer AD1. The first resin pattern RSP1 may include a plurality of first patterns P1. The first patterns P1 may be repeatedly arranged with each other in the first direction DR1 and the second direction DR2. In one or more embodiments, the first patterns P1 may be spaced and/or apart from (e.g., separated from) each other.

For example, the first patterns P1 may be formed to include a siloxane-based resin, an epoxy-based resin, an acryl-based resin, a polyvinyl alcohol-based resin, a polyacrylic acid, polyacrylimide, methylolated melamine, a butyric acid, and/or the like. These may be used alone or in combination with each other. However, the present disclosure is not limited thereto, and the first patterns P1 may be formed to include one or more other suitable materials.

The first patterns P1 may be formed by using an inkjet process, an electrohydrodynamic (EHD) process, a jetting process, and/or the like.

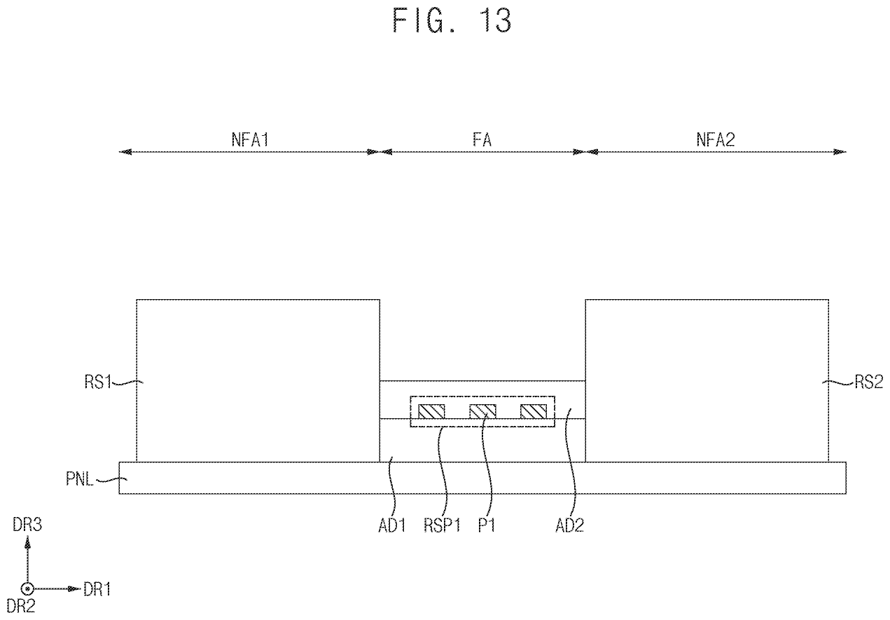

Referring to FIG. 13, a second adhesive layer AD2 may be formed to cover the first resin pattern RSP1. The second adhesive layer AD2 may be formed to include substantially the same material as the first adhesive layer AD1.

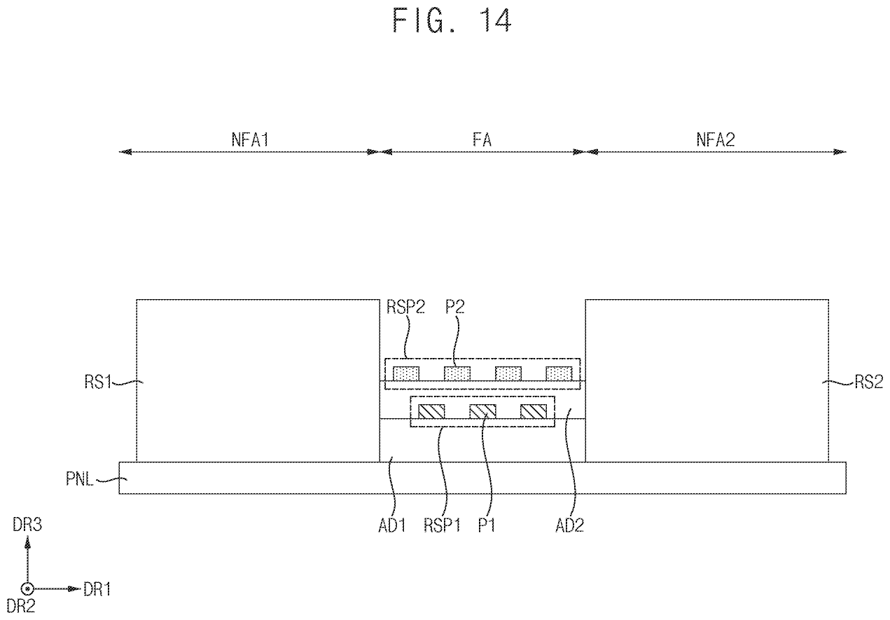

Referring to FIG. 14, a second resin pattern RSP2 may be formed on the second adhesive layer AD2. The second resin pattern RSP2 may include a plurality of second patterns P2. The second patterns P2 may be repeatedly arranged with each other in the first direction DR1 and the second direction DR2. In one or more embodiments, the second patterns P2 may be spaced and/or apart from (e.g., separated from) each other.

For example, the second patterns P2 may be formed to include a siloxane-based resin, an epoxy-based resin, an acryl-based resin, a polyvinyl alcohol-based resin, a polyacrylic acid, polyacrylimide, methylolated melamine, a butyric acid, and/or the like. These may be used alone or in combination with each other. However, the present disclosure is not limited thereto, and the second patterns P2 may be formed to include one or more other suitable materials.

The second patterns P2 may be formed by using an inkjet process, an electrohydrodynamic (EHD) process, a jetting process, and/or the like.

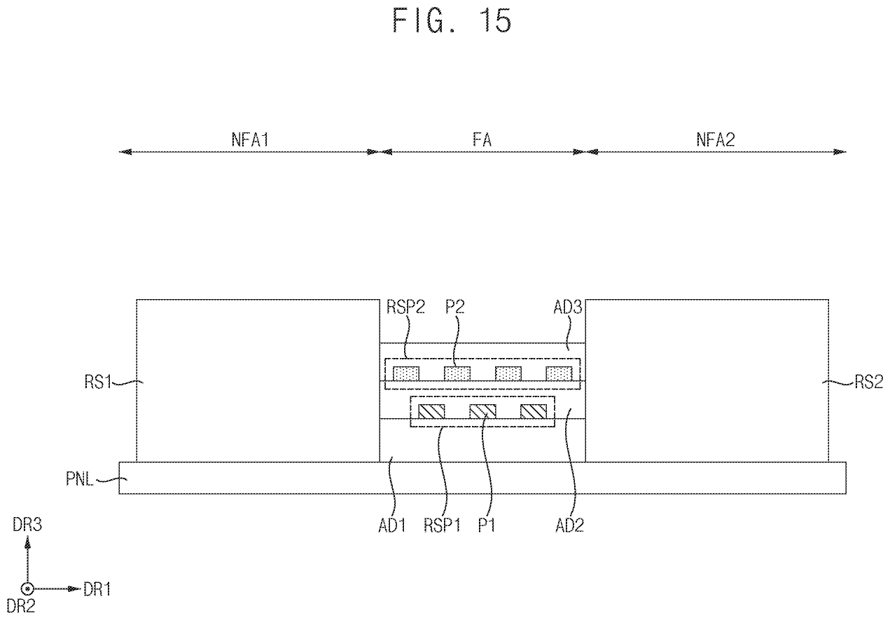

Referring to FIG. 15, a third adhesive layer AD3 may be formed to cover the second resin pattern RSP2. The third adhesive layer AD3 may be formed to include substantially the same material as the first adhesive layer AD1.

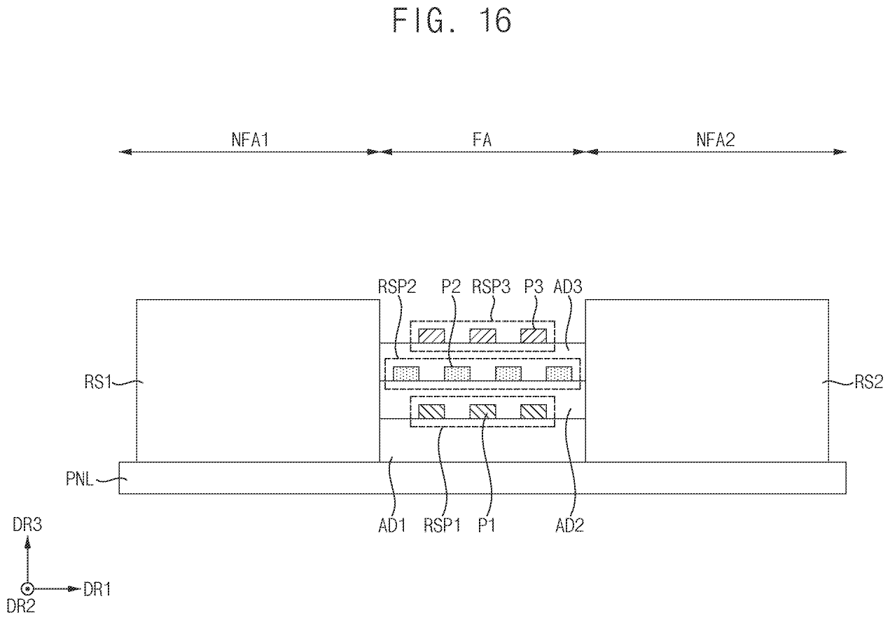

Referring to FIG. 16, a third resin pattern RSP3 may be formed on the third adhesive layer AD3. The third resin pattern RSP3 may include a plurality of third patterns P3. The third patterns P3 may be repeatedly arranged with each other in the first direction DR1 and the second direction DR2. In one or more embodiments, the third patterns P3 may be spaced and/or apart from (e.g., separated from) each other.

For example, the third patterns P3 may be formed to include a siloxane-based resin, an epoxy-based resin, an acryl-based resin, a polyvinyl alcohol-based resin, a polyacrylic acid, polyacrylimide, methylolated melamine, a butyric acid, and/or the like. These may be used alone or in combination with each other. However, the present disclosure is not limited thereto, and the third patterns P3 may be formed to include one or more other suitable materials.

The third patterns P3 may be formed by using an inkjet process, an electrohydrodynamic (EHD) process, a jetting process, and/or the like.

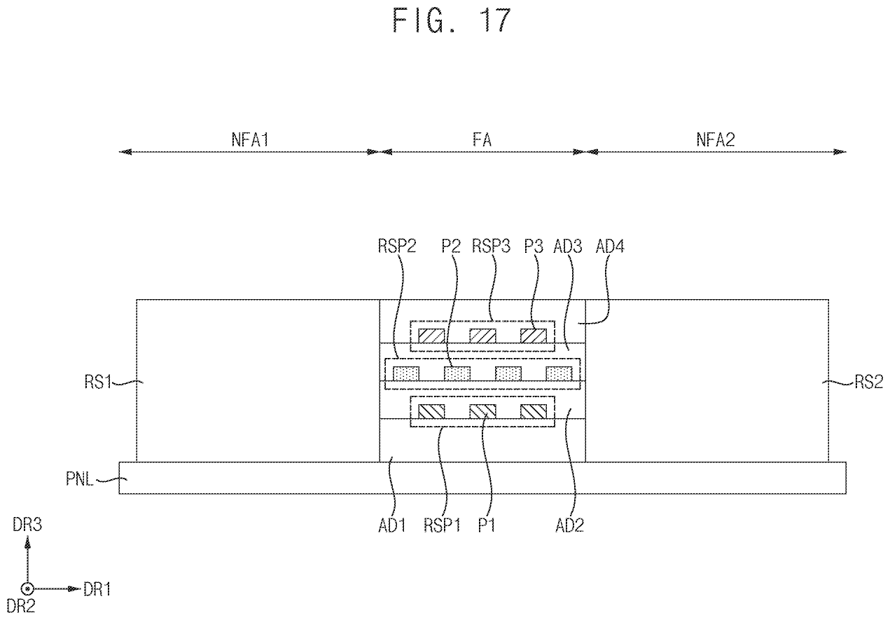

Referring to FIG. 17, a fourth adhesive layer AD4 may be formed to cover the third resin pattern RSP3. The fourth adhesive layer AD4 may include substantially the same material as the first adhesive layer AD1.

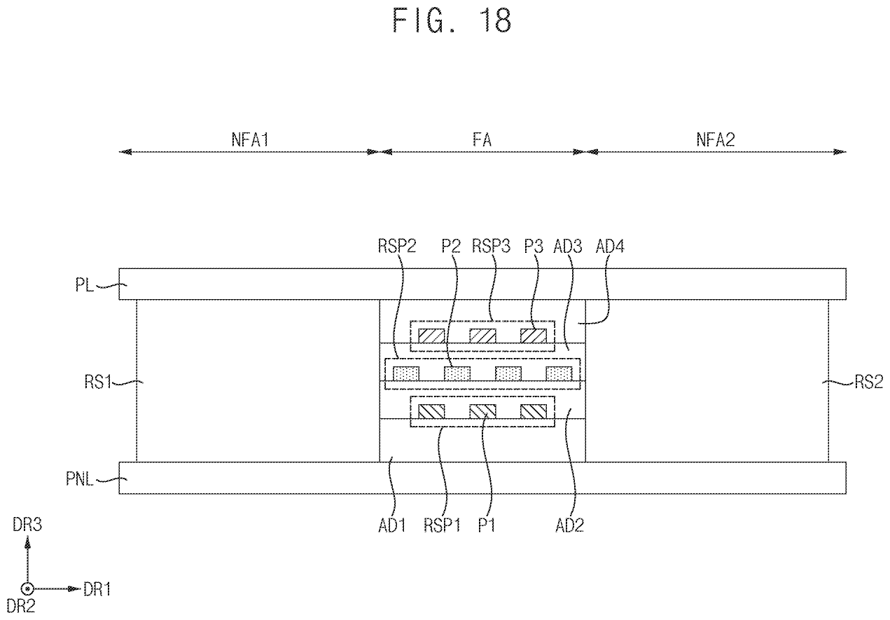

Referring to FIG. 18, a protective layer PL may be formed on the first resin layer RS1, the second resin layer RS2, and the fourth adhesive layer AD4. In one or more embodiments, the protective layer PL may be formed to include substantially the same material as the fourth adhesive layer AD4. According to one or more embodiments, the protective layer PL may be formed to include phenylene, polyethylene terephthalate, polyimide, polyamide (PA), polyethylene naphthalate, polycarbonate (PC), and/or the like. These may be used alone or in combination with each other.

Referring to FIGS. 12, 14, and 16, the first resin pattern RSP1 may be simply formed on the first adhesive layer AD1 through an inkjet process and/or the like. In one or more embodiments, the second resin pattern RSP2 may be formed on the second adhesive layer AD2 through an inkjet process and/or the like. In one or more embodiments, the third resin pattern RSP3 may be formed on the third adhesive layer AD3 through an inkjet process and/or the like. Accordingly, a process of manufacturing a window member WM and a display device (e.g., the display device DD of FIG. 1) including the window member WM may be simplified.

The present disclosure may be applied to a display device and an electronic device including the display device. For example, the present disclosure may be applied to high-resolution smartphones, mobile phones, smart pads, smart watches, tablet PCs, vehicle navigation systems, televisions, computer monitors, laptops, and/or the like.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within +30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A window member comprising:
a resin layer overlapping a non-folding region; and
an adhesive layer overlapping a foldable region, the foldable region being adjacent the non-folding region, and the adhesive layer comprising a first resin pattern, a second resin pattern on the first resin pattern, and a third resin pattern on the second resin pattern.

2. The window member of claim 1, wherein the first resin pattern comprises a plurality of first patterns repeatedly arranged with each other in a first direction and a second direction intersecting the first direction,
the second resin pattern comprises a plurality of second patterns repeatedly arranged with each other in the first direction and the second direction, and
the third resin pattern comprises a plurality of third patterns repeatedly arranged with each other in the first direction and the second direction.

3. The window member of claim 2, wherein each of the first patterns, the second patterns, and the third patterns has a hexagonal shape in a plan view.

4. A display device comprising:
a display panel comprising a non-folding region and a foldable region adjacent the non-folding region; and
a window member on the display panel and comprising a resin layer overlapping the non-folding region, and an adhesive layer comprising a first resin pattern overlapping the foldable region and a second resin pattern on the first resin pattern.

5. The display device of claim 4, wherein the first resin pattern comprises a plurality of first patterns repeatedly arranged with each other in a first direction and a second direction intersecting the first direction while being spaced apart from each other.

6. The display device of claim 5, wherein the second resin pattern comprises a plurality of second patterns repeatedly arranged with each other in the first direction and the second direction while being spaced apart from each other.

7. The display device of claim 6, wherein the adhesive layer further comprises a third resin pattern on the second resin pattern.

8. The display device of claim 7, wherein the second resin pattern is spaced apart from the first resin pattern in a third direction that is normal to a plane defined by the first direction and the second direction, and
the third resin pattern is spaced apart from the second resin pattern in the third direction.

9. The display device of claim 7, wherein the third resin pattern comprises a plurality of third patterns repeatedly arranged with each other in the first direction and the second direction while being spaced apart from each other.

10. The display device of claim 9, wherein each of the first patterns, the second patterns, and the third patterns has a polygonal shape when viewed in a plan view.

11. The display device of claim 10, wherein each of the first patterns, the second patterns, and the third patterns has a rectangular shape when viewed in the plan view.

12. The display device of claim 11, wherein the resin layer, the first resin pattern, the second resin pattern, and the third resin pattern include substantially the same material.

13. The display device of claim 12, wherein each of the resin layer, the first resin pattern, the second resin pattern, and the third resin pattern comprises at least one selected from the group consisting of a siloxane-based resin, an epoxy-based resin, an acryl-based resin, a polyvinyl alcohol-based resin, a polyacrylic acid, polyacrylimide, and a methylolated melamine resin.

14. The display device of claim 13, further comprising a protective layer on the window member, wherein the protective layer comprises substantially the same material as the resin layer.

15. A method for manufacturing a display device, the method comprising:
forming a display panel comprising a non-folding region and a foldable region adjacent the non-folding region;
forming a resin layer on the display panel and overlapping the non-folding region;
forming a first adhesive layer on the display panel and overlapping the foldable region;
forming a first resin pattern on the first adhesive layer;
forming a second adhesive layer covering the first resin pattern;
forming a second resin pattern on the second adhesive layer; and
forming a third adhesive layer covering the second resin pattern.

16. The method of claim 15, further comprising:
forming a third resin pattern on the third adhesive layer; and
forming a fourth adhesive layer covering the third resin pattern.

17. The method of claim 16, wherein the first resin pattern comprises a plurality of first patterns repeatedly arranged with each other in a first direction and a second direction intersecting the first direction,
the second resin pattern comprises a plurality of second patterns repeatedly arranged with each other in the first direction and the second direction, and
the third resin pattern comprises a plurality of third patterns repeatedly arranged with each other in the first direction and the second direction.

18. The method of claim 17, wherein each of the first patterns, the second patterns, and the third patterns has a polygonal shape when viewed in a plan view.

19. The method of claim 16, wherein the first adhesive layer, the second adhesive layer, the third adhesive layer, and the fourth adhesive layer include substantially the same material.

20. The method of claim 19, further comprising forming a protective layer on the fourth adhesive layer and the resin layer, wherein the protective layer comprises substantially the same material as the fourth adhesive layer.
